(19) United States
(12) Patent Application Publication
(10) Pub. No.: US 2006/0059409 A1
(43) Pub. Date: Mar. 16, 2006

(54) Reed-solomon decoder systems for high speed communication and data storage applications

(76) Inventor: Hanho Lee, Yeonsoo-Gu (KR)

Correspondence Address: McCARTER & ENGLISH, LLP;Attn: Angelica Brooks, CityPlace I, 185 Asylum Street, Hartford, CT, 06103, US

(21) Appl. No.: 11/222,435

(22) Filed: Sep. 8, 2005

Related U.S. Application Data
(60) Provisional application No. 60/608,704, filed on Sep. 10, 2004.

(51) Int. Cl. H03M 13/00

(52) U.S. Cl. 714/784

(57) ABSTRACT

A high-speed, low-complexity Reed-Solomon (RS) decoder architecture using a novel pipelined recursive Modified Euclidean (PrME) algorithm block for very high-speed optical communications is provided. The RS decoder features a low-complexity Key Equation Solver using a PrME algorithm block. The recursive structure enables the low-complexity PrME algorithm block to be implemented. Pipelining and parallelizing allow the inputs to be received at very high fiber optic rates, and outputs to be delivered at correspondingly high rates with minimum delay. An 80-Gb/s RS decoder architecture using 0.13-μm CMOS technology in a supply voltage of 1.2 V is disclosed that features a core gate count of 393 K and operates at a clock rate of 625 MHz. The RS decoder has a wide range of applications, including fiber optic telecommunication applications, hard drive or disk controller applications, computational storage system applications, CD or DVD controller applications, fiber optic systems, router systems, wireless communication systems, cellular telephone systems, microwave link systems, satellite communication systems, digital television systems, networking systems, high-speed modems and the like.

### CROSS-REFERENCE TO RELATED APPLICATION

The present application claims the benefit of a provisional patent application entitled “Decoder for Optical Communications,” which was filed on Sep. 10, 2004 and assigned Ser. No. 60/608,704. The entire content of the foregoing provisional patent application is incorporated herein by reference.

### BACKGROUND

1. Technical Field

The present disclosure is directed to systems and methods for error correction in data communication and data storage applications. More particularly, the present disclosure is directed to Reed-Solomon decoder systems/methods that are effective in high speed communication and data storage applications. The disclosed systems and methods may be advantageously employed in communication applications (e.g. fiber optic communication applications, routers, wireless communications systems, cellular telephone systems, microwave link systems, satellite communication systems, digital television systems, high-speed modems and the like) and storage applications (hard drive/disk controller applications, computational storage systems, tape drive controller applications, RAM controller systems, flash memory controller systems, holographic memory controller systems, and CD/DVD controllers, etc.).

2. Background Art

Reed-Solomon (RS) codes have been widely used in a variety of communication systems, such as space communication links, satellite communications, digital subscriber loops, wireless systems and networking communications, as well as in magnetic and optical storage [Ref #1]. RS decoders can be used to protect digital data against errors and to enhance signal-to-noise performance. RS codes are block-based error correcting codes that are specified as RS(n,k) with s-bit symbols, meaning that the encoder takes k data symbols of s bits each, and adds parity symbols to make an n symbol codeword. Accordingly, there are n-k parity symbols of s bites each.

The most commonly used RS decoder architecture, which can detect and correct up to t errors, consists of three main components. The first component is a Syndrome Computation (SC) block. This component generates a syndrome polynomial S(x), which is a function of the error pattern in the received codeword. This polynomial is used in the second component of the RS decoder, which is the Key-Equation Solver (KES) block, used for solving the key equation:
S(x)σ(x)=ω(x)modx^{2t}
The Euclidean Algorithm (EA) algorithm, Modified Euclidean (ME) algorithm or the Berlekamp Massey (BM) algorithm can be used to solve the key equation for an error-locator polynomial σ(x) and an error-value polynomial ω(x).

In the third component of a conventional RS decoder, both the error locator and the error value polynomials are used to determine error magnitude values corresponding to the error locations using a Chien search and Forney algorithms. The output of this block is the corrected received codeword, which is read out of the decoder. In addition, a first in/first out (FIFO) memory is generally used to buffer the symbols that are received while the decoder executes the error detection and correction process.

The very high-speed data transmission techniques that have been developed for the fiber optical networking systems have necessitated the implementation of high-speed FEC architectures to meet the continuing demands for ever higher data rates. Currently, the RS(255,239) code is commonly used in high-speed (40-Gb/s and higher) fiber optic systems. However, as data transmission rates reach and exceed 40-Gb/s, existing RS decoders using a systolic-array structure cause relatively huge hardware complexity and power consumption, which cause difficulties in system-level integration. [Ref #3-6]

An area-efficient Euclidean algorithm block for use in RS decoder applications was recently disclosed by the present inventor. [H. Lee, “An Area-Efficient Euclidean Algorithm Block for Reed-Solomon Decoder,” Proceedings of the IEEE Computer Society Annual Symposium on VLSI, February, 2003.] The disclosed architecture was effective in reducing hardware complexity relative to existing MEA block designs, and reduced latency associated with decoding functionality. However, the clock frequency and maximum data processing rate for the disclosed RS decoder using the Euclidean algorithm block was slower than other RS decoders, with clock frequency and maximum data processing rate of 300 MHz and 2.4 Gbit/s, respectively, under worst case conditions.

Thus, despite efforts to date, a need remains for RS decoder systems and methods that provide effective and reliable error correction functionality for high-speed data communication applications. In addition, a need remains for RS decoder systems and methods for high-speed data communication applications that are operable with reduced hardware complexity and/or energy requirements. Moreover, a need remains for RS decoder systems and methods that are operable at higher clock frequencies, e.g., as compared to conventional systolic-array and parallel ME algorithm blocks. These and other needs are met by the disclosed RS decoder systems and methods.

### SUMMARY OF THE DISCLOSURE

According to the present disclosure, RS decoder systems and methods are provided that advantageously supply effective and reliable error correction functionality for high-speed data communication applications. The disclosed RS decoder systems and methods are effective for error correction in high-speed data communication and data storage application applications with reduced hardware complexity and/or energy requirements. Moreover, the disclosed RS decoder systems and methods are operable at higher clock frequencies, e.g., as compared to conventional systolic-array and parallel ME algorithm blocks.

The disclosed RS decoder systems and methods employ a pipelined recursive modified Euclidean (PrME) algorithm block. The PrME algorithm block is effective in reducing the hardware complexity and improving the clock frequency of RS decoder systems, e.g., an RS(255,239) decoder. Incorporation of the disclosed PrME algorithm block into the disclosed RS decoder systems reduces the associated hardware complexity and supports operation at higher clock frequencies relative to conventional systolic-array [Ref. #3-5] and parallel ME algorithm blocks [Ref. #8]. In an exemplary embodiment of the disclosed RS decoder systems and methods, an 80-Gb/s, 16-channel RS decoder is provided for use in very high-speed optical communication applications.

The disclosed RS decoder systems and methods have widespread utility in a host of communication and data storage applications. Thus, for example, the disclosed RS decoder systems and methods with PrME algorithm blocks may be advantageously employed in communication applications (e.g. fiber optic communication applications, routers, wireless communications systems, cellular telephone systems, microwave link systems, satellite communication systems, digital television systems, high-speed modems and the like) and storage applications (hard drive/disk controller applications, computational storage systems, tape drive controller applications, RAM controller systems, flash memory controller systems, holographic memory controller systems, and CD/DVD controllers etc.).

Additional features, functions and benefits associated with the disclosed RS decoder systems and methods will be apparent to persons skilled in the art from the detailed disclosure provided herein, particularly when read in conjunction with the figures appended hereto.

### BRIEF DESCRIPTION OF FIGURES

To assist those of ordinary skill in the art in making and using the disclosed RS decoder systems and methods, reference is made to the accompanying figures, wherein:

FIG. 1 is a schematic flow chart of an exemplary RS decoder using a pipelined recursive modified Euclidian (PrME) algorithm block according to the present disclosure;

FIG. 2(a) is a schematic diagram of an exemplary syndrome cell (Sᵢ) according to the present disclosure;

FIG. 2(b) is a schematic diagram of an exemplary syndrome computation block according to the present disclosure;

FIG. 3(a) is a schematic diagram of an exemplary Chien search cell according to the present disclosure;

FIG. 3(b) is a schematic diagram of an exemplary Chien search block according to the present disclosure;

FIG. 3(c) is a schematic diagram of an exemplary Forney algorithm and error correction block according to the present disclosure;

FIG. 4(a) is a schematic diagram of an exemplary pipelined recursive modified Euclidean (PrME) algorithm block according to the present disclosure;

FIG. 4(b) is a detailed diagram of an exemplary PrME algorithm block according to the present disclosure;

FIG. 5 is a timing chart for an exemplary RS decoder using a PrME algorithm block according to the present disclosure; and

FIG. 6 is a schematic diagram of an exemplary 16-channel, 80-Gb/s RS decoder according to the present disclosure.

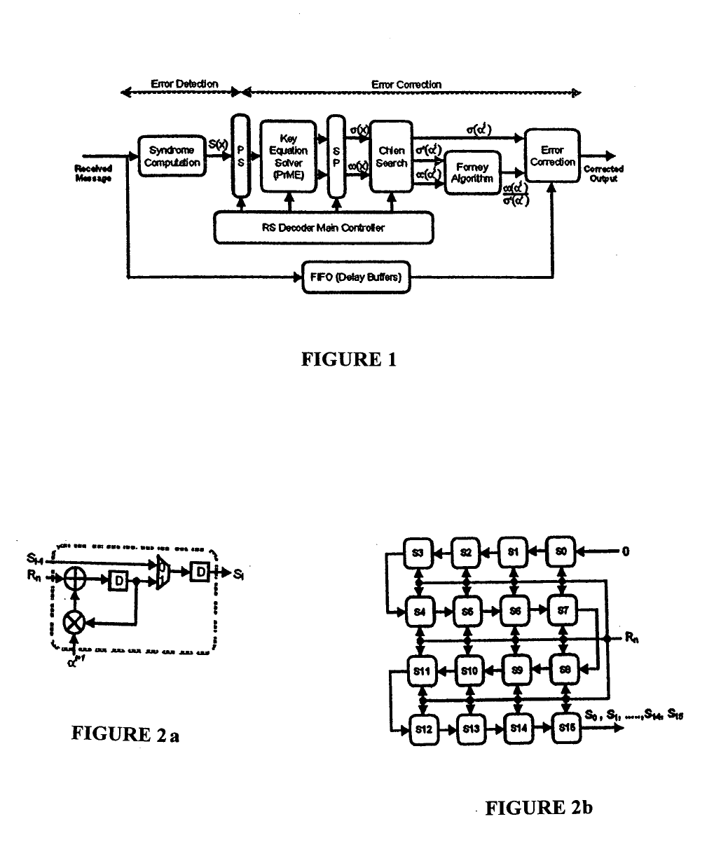

### DESCRIPTION OF EXEMPLARY EMBODIMENT(S)

RS decoder systems and methods are disclosed herein for use in forward error correction applications. The disclosed RS decoder systems and methods are particularly advantageous in high-speed data communication applications, although a wide variety of alternative applications may benefit from the disclosed RS decoder technology. Of note, the disclosed RS decoder systems and methods may be used to achieve error correction in high-speed data communication applications with reduced hardware complexity and/or reduced energy requirements. Moreover, the disclosed RS decoder systems and methods are operable at higher clock frequencies, e.g., as compared to conventional systolic-array and parallel ME algorithm blocks.

The disclosed RS decoder systems and methods employ a pipelined recursive modified Euclidean (PrME) algorithm block. The PrME algorithm block is effective in reducing the hardware complexity and improving the clock frequency of RS decoder systems, e.g., an RS(255,239) decoder. Incorporation of the disclosed PrME algorithm block into the disclosed RS decoder systems reduces the associated hardware complexity and supports operation at higher clock frequencies relative to conventional systolic-array and parallel ME algorithm blocks. As described in greater detail below, an exemplary embodiment of the disclosed RS decoder systems and methods involves an 80-Gb/s, 16-channel RS decoder for use in very high-speed optical communication applications.

As is known to persons skilled in the art, errors occur in data transmission and/or storage for a variety of reasons, e.g., noise, interference, damage to storage media, etc. An RS encoder is generally adapted to take a block of digital data and add extra, “redundant” bits to the data string. Thereafter, an RS decoder is generally adapted to process each block of digital data and attempt to correct errors and recover the original data. RS encoding and decoding according to the present disclosure can be carried out in software, special-purpose hardware or combination thereof.

RS codes are based on a mathematical field known as Galois fields or finite fields. A finite field has the property that arithmetic operation (i.e., +, −, ×, ÷, etc.) on field elements always have a result in the field. An RS encoder or decoder is adapted to carry out the requisite arithmetic operations, either through programmed software, specially adapted hardware, or combinations thereof. For purposes of the present disclosure, additional disclosure with respect to exemplary RS encoding/decoding systems and methods according to the present disclosure is provided herein below.

A. Syndrome Computation Block

For purposes of the present disclosure, C(x) and R(x) are used to designate the codeword polynomial and the received polynomial, respectively. The transmitted polynomial can be corrupted in a number of ways, e.g., channel noise, during transmission. Therefore, the received polynomial can be described as R(x)=C(x)+E(x)=Rₙ₋₁xⁿ⁻1+ . . . +R₁x+R₀, where E(x) is the error polynomial (where t is the maximum number of errors that can be corrected in the RS code). The first step in the decoding algorithm is to calculate 2t syndromes, Sᵢ, 0≦i≦2t−1, which are used to correct the correctable errors. If all 2t syndromes S_{I} (0≦i≦2t−1) are zero, then the received polynomial R(x) is a valid codeword C(x) with no transmission errors.

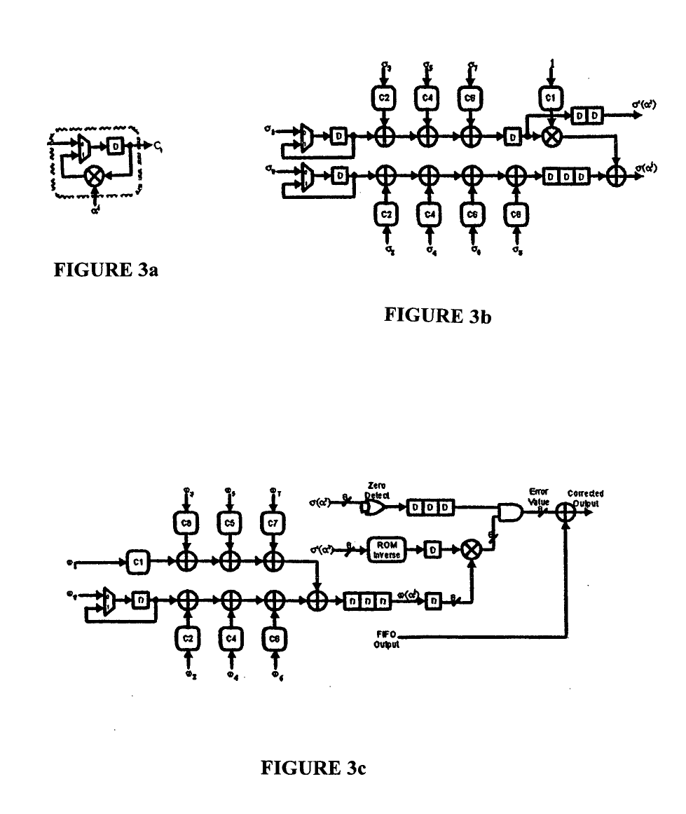

The syndrome polynomial S(x) is defined as S(x)=S₀+S₁x+ . . . +S₂ₜ₋₁x^{2t-1}=Σᵢ₋₀^{2t-1}Sⁱxⁱ, with Sᵢ=Σⱼ₌₀ⁿ⁻¹rⱼα^{ij}, where α is a root of a primitive polynomial p(x)=x⁸+x⁴+x³+x²+1 and t=8, which is a primitive element in GF(2⁸). For RS(255,239) code, αⁱ (0≦i≦254) denotes the possible error locations. The syndrome computation block shown in FIG. 2(b) accepts the received symbols, which are transmitted over a noisy channel. It considers the symbol values as being polynomial coefficients and determines if the series of symbols contained in a data block form a valid codeword for the particular RS code chosen. The syndrome computation block then evaluates the polynomial for the 2t syndrome values and detects whether or not the evaluations are zero (that is, whether or not the data block is a codeword). Any block that is not a codeword is corrupted by errors.

As shown in FIG. 2(a), the partial syndrome is multiplied by αⁱ at each cycle and accumulates with the received symbol. FIG. 2(b) shows how sixteen (16) syndrome cells are organized in an exemplary syndrome computation block. The disclosed syndrome computation block makes it possible to compute the syndromes within n symbol periods. The syndrome symbols, Sᵢ (0≦i≦15), are outputted serially to the Key Equation Solver (KES) block, as described herein below.

B. Key Equation Solver Block

The syndrome polynomial S(x) is used in the KES block for solving the key equation, S(x)τ(x)=Ω(x) mod x^{2t}. By solving this equation, the error-locator polynomial τ(x)=τᵢx^{t}+τᵢ₋₁x^{t-1}+ . . . +τ₁x¹+τ₀ and the error value polynomial ω(x)=ωₜ₋₁x^{t-2}+ . . . +ωₜ₋₂x^{t-2}+ . . . +ω₁x+ω₀ can be calculated. In conventional RS systems, the KES block is implemented using a conventional Euclidean algorithm (EA), Modified Euclidean (ME) algorithm or a Berlekamp-Massey (BM) algorithm. Indeed, division-free ME algorithms and high-speed ME algorithm blocks for RS decoding were first proposed in Ref. #3 and Ref. #5, respectively. A conventional ME algorithm blocks consist of 2t (twice the number of maximum correctable errors) processing elements (PEs) connected by means of a systolic-array structure. The hardware size of the conventional systolic-array ME algorithm blocks constitutes approximately 60% of the total RS decoder size [Ref. #3-#5]. Consequently, a key challenge that is addressed by the present disclosure is a need to minimize the hardware complexity of the ME algorithm block so that the critical path delay and the total power consumption can be reduced.

As described herein below, RS decoders of the present disclosure achieve advantageous and desirable results by employing a pipelined recursive modified Euclidian (PrME) algorithm block, thereby achieving a low-complexity RS decoder with a high throughput. According to the present disclosure, the disclosed PrME algorithm block is utilized/implemented within the KES block to reduce the hardware complexity, improve the clock frequency and provide associated advantages/benefits to the RS system and system users.

C. Chien Search and Forney Algorithm Blocks

After the KES block, the error locator polynomial (x) and the error value polynomial ω(x) are fed into a Chien search algorithm block, which calculates the roots of the error locator polynomial. The Forney algorithm block works in parallel with the Chien search block to calculate the magnitude of the error symbol at each error location.

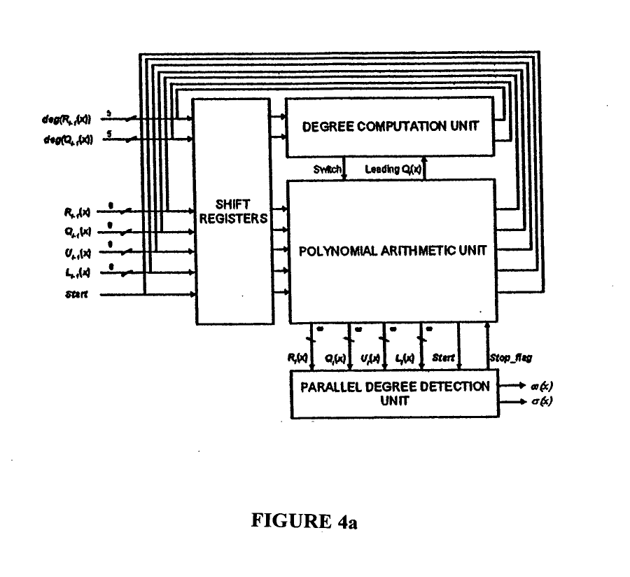

For purposes of the present disclosure, the error locator polynomial of the degree n over GF(2^{m}) may be defined by, τ(x)=τ(x)=τᵢx^{t}+τₜ₋₁x^{t-1}+ . . . +τ₀, where the coefficients τᵢεGF(2^{m}) for 0≦i≦t−1. It is well known that Chien search algorithm can be used to determine the roots of an error locator polynomial of degree t in GF(2^{m}), where t is the maximum number of errors that can be corrected in the RS code [Ref. #2]. FIGS. 3(a)-3(c) schematically depict an exemplary Chien search block, Forney algorithm and error correction blocks, respectively, which generate the error value and then the corrected symbol. For division of the Galois-field, the inverse element of the divisor is initially derived, and it is then multiplied with the element of the dividend by the pipelined fully-parallel multiplier. A straightforward approach for computation of the inverse of a non-zero element in GF(2⁸) according to the present disclosure is to use a simple look-up table composed of 255 words of 8-bits, in which the inverse values of the field elements are stored. Thus, for example, the desired values can be stored and accessed by means of a static ROM, which gives a path delay less than that of pipelined multiplier.

In the final step associated with the Chien search and Forney algorithm blocks, each error value is simply added (XORing in binary) to the received symbol fetched from a first-in/first-out (FIFO) storage location to produce the corrected symbol. At locations where there are no detected errors, the error values are zero and the received polynomial is not changed through addition at those locations.

D. FIFO Memory Buffers and Control Logic

As each error value is calculated, the corresponding received symbol is fetched from a FIFO memory, which buffers the received symbols during the decoding process. Each error value is simply added to the received symbol to produce a corrected symbol. At the locations where no errors have occurred, the error values are zero and there is no change in the received polynomial at those locations.

Since the received data coming into the RS decoder is continuous, controllers are required to generate control signals for each step of the decoding. In conventional controller designs for RS decoder systems, the controller system includes local slave controllers for each component with special handshake protocols between two successive components that are controlled through a master controller.

Pipelined Recursive Modified Euclidean Algorithm Block

A. Modified Euclidean (ME) Algorithm

As noted above, a conventional ME algorithm may be used to obtain the error locator polynomial τ(x) and the error value polynomial ω(x) by solving the key equation S(x)τ(x)=ω(x) mod x^{2t}. The ME algorithm is further described as follows:

Input: S(x), x^{2t}
Initialization:
R₀(x) = x^{2t}, Q₀(x) = S(x), L₀(x) = 0, U₀(x) = 1;
deg(R₀(x)) = 2t, deg(Q₀(x)) = 2t − 1 ;
l₀ = deg(R₀(x)) − deg(Q₀(x));
Index ‘i’ is initialized to 0;
Index ‘Step’ is initialized to 1;
Start Algorithm:
while (Step ≦ 2t) do

begin

Step [symbol] Step + 1;
i [symbol] i + 1;
aᵢ₋₁ [symbol] leading coefficient of Rᵢ₋₁(x);
bᵢ₋₁ [symbol] leading coefficient of Qᵢ₋₁(x);
if (deg(Rᵢ(x)) < t)

begin

Rᵢ(x) = Rᵢ(x);
Qᵢ(x) = Qᵢ(x);
Lᵢ(x) = Lᵢ(x);
Uᵢ(x) = Uᵢ(x);

Skip the following statements & stop the algorithm.

end

if (lᵢ₋₁ ≧ 0)

begin

| | |
|---|---|
| Rᵢ(x) = [bᵢ₋₁ Rᵢ₋₁(x)] − x^{\|li-1\|} [aᵢ₋₁ Qᵢ₋₁(x)]; | (1a) |
| Qᵢ(x) = Qᵢ₋₁(x); | (2a) |
| Lᵢ(x) = [bᵢ₋₁ Lᵢ₋₁(x)] − x^{\|li-1\|} [aᵢ₋₁ Uᵢ₋₁(x)]; | (3a) |
| Uᵢ(x) = Uᵢ₋₁(x); | (4a) |

end

else

begin

| | |
|---|---|
| Rᵢ(x) = [aᵢ₋₁ Qᵢ₋₁(x)] − x^{\|li-1\|} [bᵢ₋₁ Rᵢ₋₁(x)]; | (1b) |
| Qᵢ(x) = Rᵢ₋₁(x); | (2b) |
| Lᵢ(x) = [aᵢ₋₁ Uᵢ₋₁(x)] − x^{\|li-1\|} [bᵢ₋₁ Lᵢ₋₁(x)]; | (3b) |
| Uᵢ(x) = Lᵢ₋₁(x); | (4b) |

end

| | |
|---|---|
| lᵢ₋₁ [symbol] deg(Rᵢ₋₁(x)) − deg(Qᵢ₋₁(x)); | (5) |

end
Output: σ(x), ω(x);

In the i^{th} iteration, aᵢ₋₁ and bᵢ₋₁ are the leading coefficients of Rᵢ₋₁(x) and Qᵢ₋₁(x), respectively. The algorithm stops when deg(Rᵢ(x))<t, where deg(•) denotes the degree of a polynomial.

B. Pipelined Recursive Modified Euclidean (PrME) Algorithm Block

In the conventional ME algorithm described above, only one syndrome polynomial is computed in the time interval of one codeword. Therefore, a substantial portion of the conventional systolic-array structure in conventional systems is always idling [Refs. 3-5]. This inherent inefficiency is advantageously overcome according to the present disclosure through implementation of a pipelined recursive modified Euclidian (PrME) algorithm block. Indeed, through implementation of the disclosed PrME algorithm, exemplary embodiments of the disclosed RS decoder system use a single recursive processing element (PE) without deteriorating the data processing rate. An exemplary pipelined architecture is disclosed in Ref. #5 (H. Lee, “High-Speed VLSI Architecture for Parallel Reed-Solomon Decoder,” IEEE Trans. on VLSI Systems, Vol. 11, No. 2, pp. 288-294, April. 2003), the contents of which are hereby incorporated by reference.

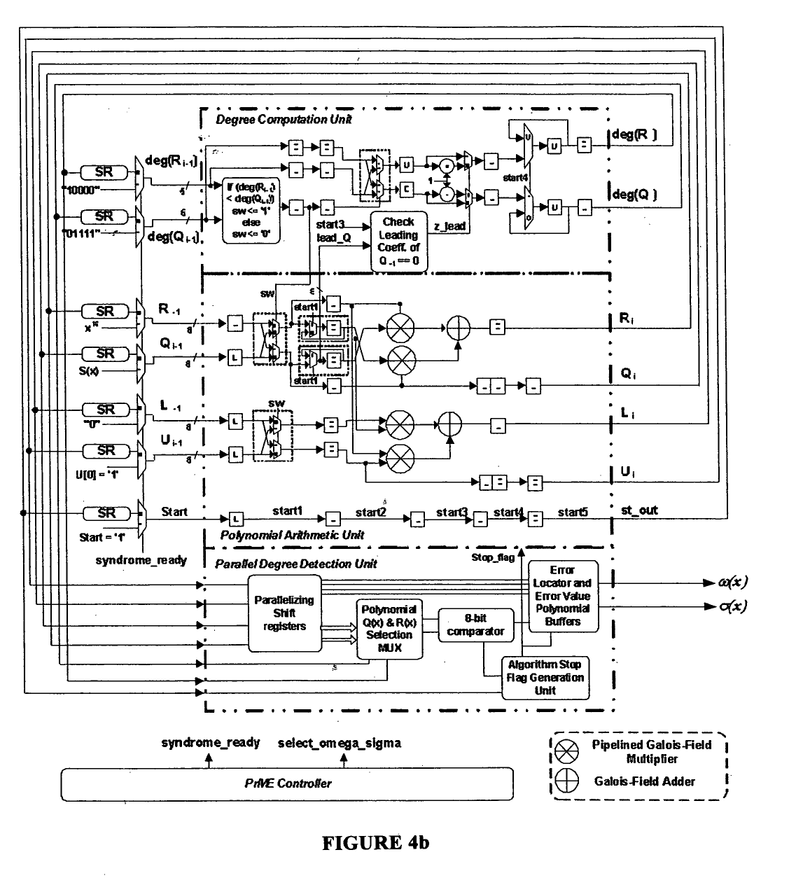

FIG. 4(a) shows a block diagram of an exemplary low-complexity PrME algorithm block according to the present disclosure. The PrME algorithm block generally includes a pipelined Degree Computation (DC) Unit, a Polynomial Arithmetic (PA) Unit, a Parallel Degree Detection (PDD) Unit, and Shift-Registers (SRs) connected by means of a recursive loop. FIG. 4(b) shows a detailed PrME algorithm block with an exemplary PDD unit. The interactions and functionalities of the various components/modules associated with the disclosed PrME algorithm block are described in greater detail below.

Degree Computation: According to exemplary embodiments of the present disclosure, the first part of the DC unit compares the degrees of the Rᵢ₋₁(x) and Qᵢ₋₁(x) polynomials using a 5-bit comparator. This comparison determines when the polynomials, Rᵢ(x) and Qᵢ(x) (from Equations 1 and 2) and the two polynomials, Lᵢ(x) and Uᵢ(x) (from Equations 3 and 4) need to be exchanged. Therefore, an exchange control circuit computes 1ᵢ₋₁ in Equation (5). The second part of the DC unit computes the degrees of both the Rᵢ(x) and Qᵢ(x) polynomials for the next modified Euclidian (ME) algorithmic iteration. These polynomial degree values are held constant until the next iteration in order to avoid any dependency between the two successive iterations because a single highly pipelined ME algorithm block is utilized recursively.

Polynomial Arithmetic: The PA unit processes the finite-field arithmetic on each polynomial Rᵢ₋₁(x), Qᵢ₋₁(x), Uᵢ₋₁(x) and Lᵢ₋₁(x), and generates the updated coefficients of each polynomial serially, which are then fed back into the PA unit in descending order. For the first iteration, a parallel to serial converter is used between the syndrome block and the PrME algorithm block in order to serialize the syndrome polynomial. The “start” signal is always aligned with the leading coefficients aᵢ₋₁ and bᵢ₋₁ of Rᵢ(x) and Qᵢ(x) polynomials, respectively, to indicate the beginning of the polynomials. The “start” signal, as well as xQ₀(x) and xU₀(x), is delayed by one time unit in such a manner that the leading coefficients of R₁(x), Q₁(x), Lᵢ(x) and U₁(x) are properly initiated by the start signal at the first iteration step of the ME algorithm.

The PA unit processes finite-field multiplications and additions. One PA unit generally contains four fully-pipelined Galois-field multipliers, two Galois-field adders, and ten multiplexers in order to calculate the Equations (1)-(4). The PA unit has five pipelining stages to provide significant improvements to the clock frequency. The eleven stage shift-registers are used to store the output of each recursive iteration step. Therefore, the PrME algorithm block typically has a total of sixteen (16) pipelining stages.

Parallel Degree Detection: The disclosed PDD structure detects and compares the degree of the Rᵢ(x) and Qᵢ(x) polynomials in parallel in order to generate the “stop” signal. At the end of each iteration step, the 5-bit degree value in the DC unit is used to address the selected line of the multiplexers. These multiplexers are used to align the coefficients of both the Rᵢ(x) and the Qᵢ(x) polynomials. If the 8-most significant coefficients of both polynomials are zeros, the 8-least significant coefficients are compared, and then a “stop” signal is generated. The “stop” signal is used as a second level synchronous reset for all registers in the PrME algorithm block, which puts the PA unit and the DC unit in the low-power mode. If Rᵢ(x)>Qᵢ(x), then error-locator polynomial τ(x) is Lᵢ(x) and the error value polynomial ω(x) is Rᵢ(x). Otherwise, τ(x) is Uᵢ(x) and ω(x) is Qᵢ(x).

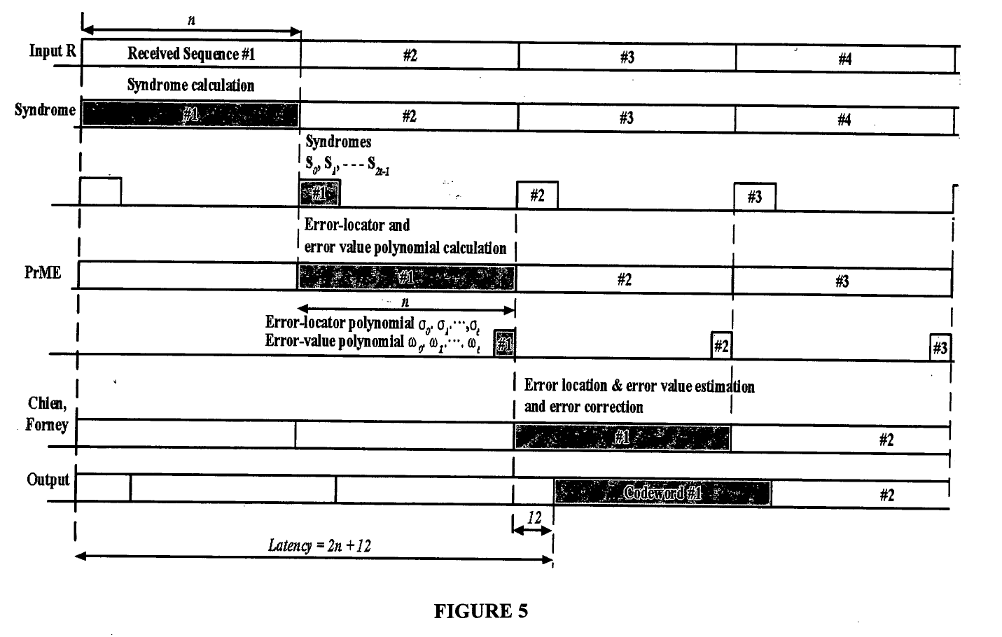

FIG. 5 shows an exemplary timing chart for an RS decoder using the PrME algorithm block of the present disclosure. The syndrome computation block provides 2t syndromes after n clock cycles processing delay required for computing the syndrome polynomial. The PrME algorithm block accepts the syndromes and feeds back the output at each iteration step. After n clock cycles, the PrME algorithm block outputs the τ(x) and ω(x) polynomials in a parallel feed to the Chien search block. The disclosed RS decoder continuously takes in code blocks, performs the appropriate coding operation, and outputs the data with a fixed latency of 2n+12 clock cycles.

Thus, the disclosed PrME significantly enhances the functionality and efficiency of an RS decoder system, reducing the latency associated with error processing while reducing the hardware requirements and reducing energy requirements.

### EXAMPLE

### 80-GB/S 16-Channel Reed-Solomon Decoder

In order to reduce critical path delays associated with conventional RS decoder systems, all components of the exemplary RS decoder were pipelined deeply. Therefore, the disclosed RS decoder is a fully pipelined structure, running at a much faster clock rate. Taking advantage of the high-speed and low-complexity of the disclosed RS decoder structure, it is possible to provide a multi-channel RS decoder that is capable of handling much higher data rates. The disclosed structure has m-parallel replication fingers of the RS decoder block. This means that there are m-channels with m RS decoders working independently with respect to the core decoder logic, but sharing the same controllers. A simple brute-force replicated implementation was chosen to keep the control logic in its simplest form. As the bandwidth of all the key components of the RS decoder is fully utilized, the time-multiplexing of the disclosed RS decoder is not possible without dedicating multiple ME algorithm blocks in a single channel. For this reason, the exemplary multiple channel RS decoder structure described herein was implemented using identical RS decoder fingers.

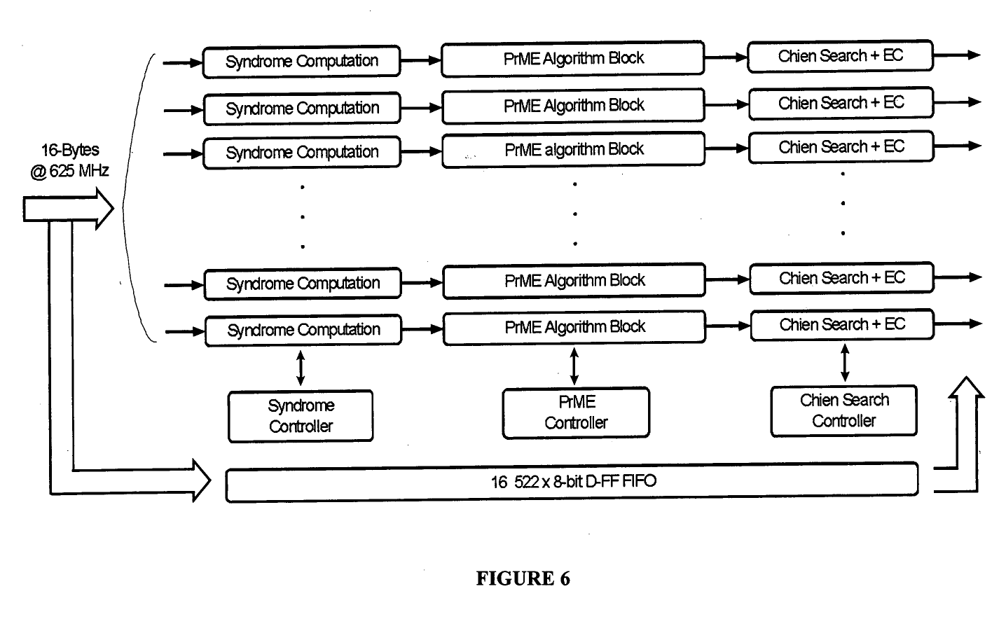

As the data rate reaches 40-Gb/s and beyond, the hardware complexity and power consumption of the RS decoders can become barriers to their low cost integration. Therefore, the high-speed, low-complexity RS decoder of the present disclosure can be used in a multiple channel configuration to obtain desired throughput. Using a 5-Gb/s RS decoder channel, the 40-Gb/s RS decoder can be implemented using 8-channels and an 80-Gb/s RS decoder can be implemented using 16-channels. FIG. 6 shows an exemplary 16-channel RS decoder for supporting 80-Gb/s data rates according to the present disclosure.

The disclosed RS decoder using the PrME algorithm block was first modeled in Verilog HDL and functionally verified using a ModelSim simulator. The outputs from the Verilog coded architecture were validated against a bit-accurate C-coded model. After functional validation, the architecture was synthesized for the appropriate time and area constraints using SYNOPSYS' Design Compiler. TSMC 0.13-μm CMOS technology and standard cell library (which was optimized for a 1.2 V supply voltage) were utilized.

A. 1-Channel RS Decoder

Table I shows a comparison of the critical path delay and latency for various KES blocks. The table shows that the disclosed PrME algorithm block has almost the same critical path delay as the previous systolic-array ME algorithm block [Ref. #5], and has a significantly lower critical path delay than the Euclidean algorithm [Ref #6] and the BM algorithm [Ref. #7] blocks.

TABLE I
Comparison of the critical path delay and latency for KES blocks

| Architecture | Critical path delay | Latency |
|---|---|---|
| PrME [Present disclosure] | 3Tₒᵣ₂ + Tₓₙₒᵣ₂ + Tₘᵤₓ₂ + T_{ff} | 2n + 12 |
| Systolic ME [Ref. #5] | 3_{Tor2} + Tₓₙₒᵣ₂ + Tₘᵤₓ₂ + T_{ff} | 10t |
| EA [Ref. #6] | Tᵣₒₘ + T_{and2} + 2Tₘᵤₗₜ + | 2t |
| | T_{add} + 2Tₘᵤₓ₂ + T_{ff} | |
| RiBM [Ref. #7] | Tₘᵤₗₜ + T_{add} + T_{ff} | 2t |
| Parallel ME [Ref. #8] | Tₘᵤₗₜ + T_{add} + T_{ff} | 2t + 2 |

Table II summarizes the hardware complexity of the various KES architectures. It can be seen that, in comparison with the conventional KES blocks, the disclosed PrME algorithm block requires only four (4) finite-field multipliers and two (2) finite-field adders. As a result, the data set forth in Table II demonstrates that significantly reduced hardware-complexity may be achieved with the RS decoder systems utilizing a PrME algorithm block of the present disclosure as compared to RS decoders that employ a conventional ME algorithm block [Ref. #5, Ref #8], Euclidean algorithm block [Ref. #6], and BM algorithm block [Ref. #7].

TABLE II
Comparison of the hardware complexity for the KES Blocks

| | Disclosed | Systolic | EA | RiBM | Parallel |
|---|---|---|---|---|---|
| | PrME | ME [#5] | [#6] | [#7] | ME [#8] |
| Multipliers | 4 | 8t | 3t + 1 | 6t + 2 | 6t + 2 |
| Adders | 2 | 8t | 4t + 1 | 3t + 1 | 3t + 1 |
| D-FFs | 170 | 78t + 4 | 14t + 6 | 6t + 2 | 6t + 4 |
| MUXes | 30 | 40t + 2 | 11t + 4 | 3t + 1 | N/A |

Table III compares the gate count, clock rate, latency and throughput of several RS decoders. By comparing the core logic of the RS decoders (without FIFO memory), it is clear that the disclosed RS decoder systems of the present disclosure require only 20% and 44% of the gate count of the RS decoders using conventionally disclosed systolic-array ME algorithm [Ref. #5] and Euclidean algorithm [Ref #6], respectively. It can also be seen from the data set forth in Table III that comparing the RS decoder of the present disclosure with an RS decoder using a parallel MEA block [Ref. #8], the disclosed RS decoder requires only 63% of the gate count. Indeed, the disclosed RS decoder operates at a clock rate of 625 MHz, has a latency of 0.83 μs, and a throughput of 5-Gb/s.

TABLE III
Implementation results of the RS(255, 239) Decoders

| | Disclosed | Systolic | Parallel | |
|---|---|---|---|---|
| Design | PrME | ME [#5] | ME [#8] | EA [#6] |
| Syndrome | 3,000 | 3,000 | 2,500 | 3,000 |
| KES | 17,000 | 117,500 | 21,000 | 44,700 |
| Chien, Forney, | 4,600 | 4,600 | 15,000 | 4,600 |
| Error | | | | |
| Total # of | 24,600 | 124,600 | 38,500 | 55,600 |
| Gates | | | | |
| Clock Rate | 625 | 625 | 112 | 300 |
| (MHz) | | | | |
| Latency | 522 | 355 | 168 | 287 |
| (clocks) | (0.83 μs) | (0.57 μs) | (1.5 μs) | (0.96 μs) |
| Throughput | 5 | 5 | 2.5 | 2.4 |
| (Gb/s) | | | | |

Table IV compares the gate count for a 16-channel implementation of the RS decoders for high-data rates. A recent implementation of a high-speed 16-channel RS decoder for optical communication was published in [Ref. #8]. Implemented in 0.16-μm CMOS technology with a supply voltage of 1.5 V, the reference 40-Gb/s RS decoder core logic using a parallel ME algorithm block has a gate count of 364 K and a clock rate of 112 MHz. Supporting precisely the same 16-channel RS(255,239) FEC code, a 16-channel RS decoder according to the present disclosure has a 80-Gb/s data processing rate and a gate count of 393 K. As a result, the disclosed 80-Gb/s RS decoder core logic complexity is similar to that of the 40-Gb/s design, while its data processing rate is significantly higher.

TABLE IV
Implementation Results of the 16-Channel RS Decoders.

| | Disclosed | Systolic | Parallel |
|---|---|---|---|
| Design | PrME | ME [#5] | ME [#8] |
| Syndrome | 48,000 | 48,000 | 40,000 |
| KES | 272,000 | 468,000 | 84,000 |
| Chien, Forney, | 73,000 | 73,000 | 240,000 |
| Error | | | |
| Total # of Gates | 393,000 | 589,000 | 364,000 |
| Clock Rate (MHz) | 625 | 625 | 112 |
| Throughput (Gb/s) | 80 | 80 | 40 |
| Technology | 0.13 μm, 1.2 V | 0.13 μm, 1.2 V | 0.16 μm, 1.5 V |

Thus, as disclosed herein, a high-speed, low-complexity RS decoder for very high-speed communications and/or data storage applications is provided. A high-speed, low-complexity PrME algorithm block is disclosed herein and, in exemplary embodiments, is applied to the design of RS decoder architecture. The recursive structure enables an advantageous low-complexity PrME algorithm block to be implemented. Pipelining and parallelizing allow the inputs to be received at very high rates, e.g., at rates supported by fiber optic transmission systems, and the outputs to be delivered at correspondingly high rates with a minimum delay. As a result, an exemplary 80-Gb/s RS decoder using the disclosed PrME algorithm block has a hardware complexity that is comparable to a previously published 40-Gb/s RS decoder design. The 80-Gb/s RS decoder has higher throughput implementations than is shown in the published literature and has countless potential applications, including the next generation FEC devices for optical communications with a data rate of 40-Gb/s and beyond.

Although the present disclosure has been described with reference to exemplary embodiments and implementations of the disclosed RS decoder systems and methods, the present disclosure is not limited to such exemplary embodiments and implementations. Rather, the disclosed RS decoder systems and methods are susceptible to various modifications, alterations and/or enhancements without departing from the spirit or scope of the present disclosure. Accordingly, such modifications, alterations and/or enhancements as would be apparent to persons skilled in the art from the detailed description provided herein are expressly encompasses within the scope of the present invention.

### REFERENCES

[1] “Forward Error Correction for Submarine Systems,” Telecommunication Standardization Section, International Telecom. Union, ITU-T Recommendation G.975, October 2000.
[2] S. B. Wicker, “Error Control Systems for Digital Communication and Storage,” Prentice Hall, 1995.
[3] H. M. Shao, T. K. Truong, L. J. Deutsch, J. H. Yuen and I. S. Reed, “A VLSI Design of a Pipeline Reed-Solomon Decoder,” IEEE Trans. on Computers, Vol. C-34, No. 5, pp. 393-403, May 1985.
[4] W. Wilhelm, “A New Scalable VLSI Architecture for Reed-Solomon Decoders,” IEEE Jour. of Solid-State Circuits, Vol. 34, No. 3, March 1999.
[5] H. Lee, “High-Speed VLSI Architecture for Parallel Reed-Solomon Decoder,” IEEE Trans. on VLSI Systems, Vol. 11, No. 2, pp. 288-294, April. 2003.
[6] H. Lee, “An Area-Efficient Euclidean Algorithm Block for Reed-Solomon Decoder,” IEEE Computer Society Annual Symposium on VLSI, pp. 209-210, February 2003.
[7] D. V. Sarwate and N. R. Shanbhag, “High-Speed Architecture for Reed-Solomon Decoders,” IEEE Trans. on VLSI Systems, Vol. 9, No. 5, pp. 641-655, October 2001.
[8] L. Song, M-L. Yu and M. S. Shaffer, “10 and 40-Gb/s Forward Error Correction Devices for Optical Communications,” IEEE Journal of Solid-State Circuits, Vol. 37, No. 11, pp. 1565-1573, November 2002.

1. An RS decoder system comprising:
a. a Key Equation Solver (KES) block, wherein said key equation solver block includes processing functionality that is configured to run a pipelined recursive modified Euclidian (PrME) algorithm to solve a key equation associated with a forward error correction (FEC) utility.

2. An RS decoder system according to claim 1, wherein the key equation takes the form S(x)τ(x)=ω(x)mod x^{2t}, where S(x) is a syndrome polynomial, τ(x) is an error-locator polynomial, ω(x) is an error-value polynomial, and t is the maximum number of errors that can be corrected.

3. An RS decoder system according to claim 1, wherein the KES block is configured to process data at a rate of at least about 80 Gb/s.

4. An RS decoder system according to claim 1, wherein the key equation solver block is configured to process data at a clock rate of at least about 625 MHz.

5. An RS decoder system according to claim 1, wherein said KES block is incorporated into a data processing application selected from the group consisting of a fiber optic telecommunication application, a hard drive or disk controller application, a computational storage system application, a CD or DVD controller application, and a communication system application.

6. An RS decoder system according to claim 5, wherein said communication system application includes a data processing application selected from the group consisting of a fiber optic system, a router system, a wireless communication system, a cellular telephone system, a microwave link system, a satellite communication system, a digital television system, a networking system, and a high-speed modem.

7. An RS decoder system according to claim 1, further comprising a syndrome computation block.

8. An RS decoder system according to claim 7, wherein said syndrome computation block is adapted to generate a syndrome polynomial S(x).

9. An RS decoder system according to claim 1, wherein the KES block is adapted to communicate with a processing unit that runs a Chien search and Forney algorithm.

10. An RS decoder system according to claim 1, further comprising a first in/first out memory that is configured to buffer data flow while the KES block runs the PrME algorithm.

11. An RS decoder system according to claim 1, wherein said KES block is adapted to operate with a RS(255,239) code.

12. An RS decoder system according to claim 1, wherein said PrME algorithm is carried out in software, hardware or a combination thereof.

13. An RS decoder system, comprising:
a. a syndrome computation block,
b. a KES block in communication with the syndrome computation block, and
c. a Chien search algorithm block in communication with the KES block;
d. a Forney algorithm block that functions in parallel with the Chien search block;
wherein the KES block is adapted to run a pipelined recursive modified Euclidian (PrME) algorithm to solve a key equation associated with a forward error correction (FEC) utility and effect at least one error correction with respect to a data stream fed to said syndrome computation block.

14. An RS decoder system according to claim 13, wherein said data stream is fed to said syndrome computation block at a rate of at least about 80 Gb/s.

15. An RS decoder system according to claim 13, wherein data output from the Chien search algorithm block and the Forney algorithm block includes any error corrections identified in the RS decoder system, and further comprising a first in/first out memory storage buffer in communication with said data output for transmission of an initial data stream for combination with said error corrections.

16. A method for effecting error corrections to a data stream, comprising:
a. providing an RS decoder system that includes a KES block, said key equation solver block adapted to operate a pipelined recursive modified Euclidean (PrME) algorithm,
b. transmitting data to said key equation solver block;
c. processing said data using said PrME algorithm, and
d. effecting any error corrections identified in said data through operation of said PrME algorithm.

17. A method according to claim 16, wherein said RS decoder system further comprises a syndrome computation block, a Chien search block and a Forney algorithm block.

18. A method according to claim 16, wherein said RS decoder system is adapted to process data at a rate of at least about 80 Gb/s.

19. A method according to claim 16, wherein said RS decoder system is adapted to process data at a clock speed of at least about 625 MHz.

20. A method according to claim 16, wherein said RS decoder system forms part of a communication system selected from a fiber optic telecommunication application, a hard drive or disk controller application, a computational storage system application, a CD or DVD controller application, a fiber optic system, a router system, a wireless communication system, a cellular telephone system, a microwave link system, a satellite communication system, a digital television system, a networking system, and a high-speed modem.
